(19) United States
(12) Patent Application Publication
(10) Pub. No.: US 2025/0266249 A1
(43) Pub. Date: Aug. 21, 2025

(54) PLASMA ETCHING APPARATUS AND PLASMA ETCHING METHOD

(71) Applicant: Samsung Electronics Co., Ltd., Suwon-si (KR)

(72) Inventors: Woorim LEE, Suwon-si (KR); Inseong KIM, Suwon-si (KR); Tongkyun KIM, Suwon-si (KR); Sunggil KANG, Suwon-si (KR); Sungyong PARK, Suwon-si (KR)

(73) Assignee: Samsung Electronics Co., Ltd., Suwon-si (KR)

(21) Appl. No.: 19/038,949

(22) Filed: Jan. 28, 2025

(30) Foreign Application Priority Data
Feb. 19, 2024 (KR) 10-2024-0023432

(51) Int. Cl. H01J 37/32

(52) U.S. Cl. CPC H01J 37/32834; H01J 37/32981; H01J 2237/334

(57) ABSTRACT

A plasma etching apparatus may include a chamber having an upper wall, a lower wall, and side walls defining a plasma process space; a substrate stage in the chamber and configured to have a wafer loaded thereon; a gas supplier to supply gas onto the wafer; a gas exhaust portion having an exhaust pipe to exhaust gas from the chamber to control pressure therein; a valve mechanism having a first collection valve at a portion of a first gas collection pipe, the first gas collection pipe connected to the plasma process space, and a discharge valve at a portion of a gas discharge pipe connected to the exhaust pipe; and a monitoring apparatus having a first collection line connected to the first collection valve, a gas analyzer to analyze gas introduced through the first collection line, and a discharge line to discharge the gas.

### PRIORITY STATEMENT

This application claims priority under 35 U.S.C. § 119 to Korean Patent Application No. 10-2024-0023432, filed on Feb. 19, 2024, in the Korean Intellectual Property Office (KIPO), the contents of which are herein incorporated by reference in their entirety.

### BACKGROUND

### 1. Field

At least some example embodiments relate to a plasma etching apparatus using gas and/or to plasma etching methods using the same. For example, some example embodiments relate to a plasma etching apparatus having a monitoring apparatus for analyzing injected gas and/or to plasma etching methods using the same.

### 2. Description of the Related Art

As line widths of semiconductor products decrease, a relatively high selectivity may be advantageous for removal of specific materials during an etching process. However, in, for example, a dry etching process using gases, various chemical reactions such as, for example, adsorption, recombination, and/or consumption may occur on a chamber surface until the gas injected into the chamber reaches the wafer, which may cause or be associated with changes in composition and ratio of etching species. In addition, if a catalyst material deposited on an inner surface of the chamber and used as a precursor, etc., changes due to long-term use of an etching apparatus, this may limit obtaining and/or securing of process reproducibility. Accordingly, it may be advantageous to monitor the composition and/or ratio of the etching species in the process space in order to achieve and/or maintain process performance at constant or desired levels.

### SUMMARY

At least some example embodiments relate to a plasma etching apparatus having, for example, a monitoring apparatus that is configured to analyze etching species in a process space.

At least some example embodiments relate to plasma etching methods using the plasma etching apparatus.

According to some example embodiments, a plasma etching apparatus may include a chamber having an upper wall, a lower wall, and side walls, the chamber at least partially defining a plasma process space between the upper wall and the lower wall; a substrate stage in the chamber and configured to support a wafer in the chamber; a gas supplier configured to supply a gas onto the wafer; a gas exhaust portion having an exhaust pipe, the exhaust pipe configured to exhaust gas from the chamber and configured to control pressure inside the chamber; a valve mechanism having a first collection valve at an end portion of a first gas collection pipe, the first gas collection pipe fluid communication with the plasma process space and a discharge valve at an end portion of a gas discharge pipe, the discharge pipe in fluid communication with the exhaust pipe; and a monitoring apparatus having a first collection line detachably connected to the first collection valve, a gas analyzer configured to analyze gas introduced through the first collection line, and a discharge line configured to discharge the analyzed gas.

According to some example embodiments, an plasma etching apparatus may include a chamber having an upper wall at least partially defining a plurality of through holes, a lower wall at least partially defining an exhaust hole, and side walls at least partially defining a plasma process space between the upper wall and the lower wall; a substrate stage in the chamber and having a seated surface configured to support a wafer; a gas supplier configured to supply gas in the wafer through a plurality of through holes at least partially defined by the chamber; an exhaust portion having an exhaust pipe and a pump, the exhaust pipe connected to the pump, the exhaust portion configured to control pressure in the chamber; a plasma generator configured to generate plasma from gas supplied through the plurality of through holes; a valve mechanism having a first collection valve at an end portion of a first gas collection pipe that is connected to the side walls of the chamber, the first gas collection pipe configured to collect gas in the plasma process space, and a discharge valve at an end portion of a gas discharge pipe, the gas discharge pipe connected to the exhaust pipe, the exhaust pipe configured to exhaust collected gas; and a monitoring apparatus having a first collection line detachably connected to the first collection valve, a gas analyzer configured to analyze gas introduced through the first collection line, and a discharge line detachably connected to the discharge valve and configured to discharge the analyzed gas.

According to some example embodiments, a plasma etching apparatus may include a chamber having an upper wall at least partially defining a plurality of through holes, a lower wall at least partially defining an exhaust hole, and side walls at least partially defining a plasma process space between the upper wall and the lower wall; a substrate stage in the chamber and configured to have a wafer loaded thereon; a gas supplier configured supply gas onto the wafer through the plurality of through holes; a baffle plate provided between the upper wall of the chamber and the substrate stage and at least partially defining a plurality of gas distribution holes; a gas exhaust portion having an exhaust pipe in fluid communication with the exhaust hole, a chamber outlet valve configured to control pressure in the chamber, and a pump configured to exhaust gas from the chamber; a valve mechanism having a first collection valve provided at an end portion of a first gas collection pipe, the first gas collection pipe in fluid communication with the plasma process space, and an discharge valve at an end portion of a gas discharge pipe, the gas discharge pipe in fluid communication with the exhaust pipe; a monitoring apparatus having a first collection line detachably connected to the first collection valve, a gas analyzer configured to analyze gas introduced through the first collection line, and a discharge line detachably connected to the discharge valve and configured to discharge the analyzed gas; and a controller configured to receive data from the monitoring apparatus, the data indicating a ratio of gas, and the controller configured to change a process condition of the plasma etching apparatus . . .

### BRIEF DESCRIPTION OF THE DRAWINGS

FIG. 1 is a cross-sectional view illustrating a plasma etching apparatus in accordance with some example embodiments.

FIGS. 2 to 15 are views illustrating a plasma etching method in accordance with some example embodiments.

FIG. 16 is a cross-sectional view illustrating a plasma etching apparatus in accordance with some example embodiments.

FIG. 17 is a cross-sectional view illustrating a plasma etching apparatus in accordance with some example embodiments.

### DETAILED DESCRIPTION

Hereinafter, some example embodiments will be explained in detail with reference to the accompanying drawings.

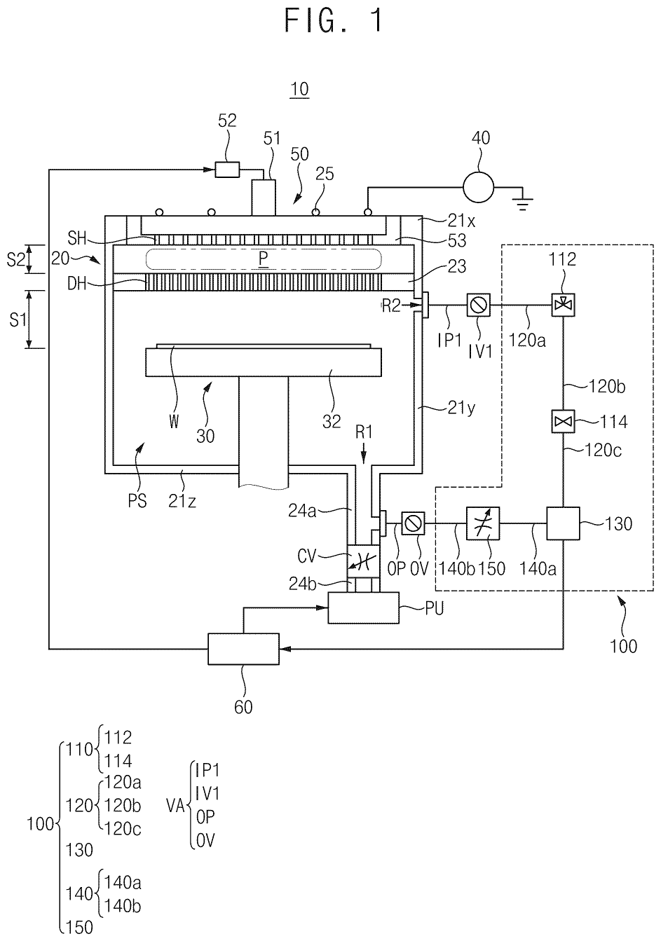

FIG. 1 is a cross-sectional view illustrating a plasma etching apparatus in accordance with some example embodiments.

Referring to FIG. 1, a plasma etching apparatus 10 may include a chamber 20 having an inner space PS, a substrate stage 30 provided in the chamber 20 and on which a wafer is loaded, a gas supplier 50 configured to inject gas into the chamber 20, a controller 60, and a plasma control portion. The plasma control portion may include an antenna 25 configured to form plasma in the chamber 20 and a source power circuitry 40 configured to apply a high frequency power source to the antenna. Additionally, the plasma etching apparatus may further include a valve mechanism VA that is in fluid communication with the inner space of the chamber 20 and a monitoring apparatus 100 that is detachably connected to the valve mechanism VA and is configured to analyze gas in the chamber 20.

For example, the plasma etching apparatus may be an apparatus configured to perform an etching process in order to partially or at least partially remove a portion of an object layer on the wafer. The etching process may be or include a dry etching process that removes a specific material by utilizing a gas in a gaseous state. For example, the etching process may be or include a plasma etching process utilizing a plasma control portion to convert an injected gas into a plasma state. In such a case, the plasma control portion may be, for example, an inductively coupled plasma (ICP) type. Alternatively, for example, the plasma control portion may be a capacitively coupled plasma (CCP) type, but example embodiments are not limited thereto.

In some example embodiments, the chamber 20 may include chamber outer walls 21 defining or at least partially defining the inner space PS, a baffle plate 23 configured to distribute injected gas, an exhaust portion 24 that is provided at a portion of the chamber outer walls 21 and is in fluid communication with the inner space PS, and an antenna 25 provided on the chamber 20. For example, the inner space of the chamber may be sealed so that an inner pressure of the inner space can be controlled to a desired vacuum level by the exhaust portion, but example embodiments are not limited thereto.

The chamber outer walls 21 may include an upper wall 21x with a gas supplier, which is described later, a lower wall 21z with an exhaust portion 24, and a plurality of side walls 21y provided between the upper wall 21x and the lower wall 21z and defining or at least partially defining the inner space PS. For example, the upper wall 21x and the lower wall 21z may extend along horizontal direction facing each other, and the plurality of side walls 21y may respectively extend along vertical direction to connect between the upper wall 21x and the lower wall 21z.

The substrate stage 30 may be provided within the inner space PS of the chamber 20 and may include a substrate support 32 onto which the wafer W is loaded. For example, the substrate support may include a seated surface, facing the upper wall 21x, on which the wafer W is seated.

The baffle plate 23 may be provided between the substrate stage 30 and the upper wall 21x of the chamber 20, and may include a plurality of gas distribution holes DH therein. For example, the baffle plate may be configured to filter ions from gas passing through the plurality of gas distribution holes DH. The plurality of gas distribution holes DH of the baffle plate may distribute the gas such that the gas is, for example, evenly or substantially evenly distributed over the wafer.

The inner space PS may include a plasma process space S1 and a distribution space S2, which are separated based on (for example, be understood as separated by) the baffle plate 23. The plasma process space S1 may be provided (for example, defined or at least partially defined) between the baffle plate 23 and the loaded wafer W. The plasma process space may be a space where injected gas is in contact (for example, direct contact) with the wafer to perform the plasma etching process. The distribution space S2 may be provided between (for example, vertically between) the baffle plate 23 and the upper wall 21x of the chamber 20. The distribution space may be a space where gas injected into the chamber is converted to a plasma state by the plasma control portion.

Although the figures illustrate that the plasma P is provided in the distribution space S2 between (for example, defined or at least partially defined between) the baffle plate 23 and the chamber upper wall 21x, the present inventive concepts may not be limited thereto. Accordingly, the location of the plasma may be changed depending on the plasma control portion.

The exhaust portion 24 may include a first exhaust pipe 24a, a second exhaust pipe 24b, and a pump PU. Additionally, the exhaust portion 24 may include a chamber outlet valve CV provided between the first exhaust pipe 24a and the second exhaust pipe 24b. The exhaust portion 24 may be provided on or adjacent to the lower wall 21z of the chamber 20. For example, the pump may be or include, for example, a dry pump and/or a turbo-molecular pump (TMP), but example embodiments are not limited thereto.

The gas injected into the chamber 20 may be discharged through the first exhaust pipe 24a, the chamber outlet valve CV and the second exhaust pipe 24b that are sequentially connected to a first recess, which may be or include an exhaust hole R1 provided in (for example, defined or at least partially defined by) the lower wall 21z.

The chamber outlet valve CV may be or include, for example, a flow control valve configured to control flow rate(s) of flow through an interior of the flow control valve by controlling a size of an inner cross-sectional area through which flow moves (for example, occurs). The chamber outlet valve may regulate an amount of gas discharged from the inner space of the chamber, thereby maintaining the inner space PS of the chamber 20 at desired (for example, constant) pressure level or levels. For example, the chamber outlet valve may be a throttle valve, but example embodiments are not limited thereto.

In some example embodiments, the valve mechanism VA may include a first gas collection pipe IP1 in fluid communication with the plasma process space S1 in the chamber 20, a first collection valve IV1 provided at an end portion of the first gas collection pipe IP1, a gas discharge pipe OP in fluid communication with the exhaust pipes 24a and 24b, and a discharge valve OV provided at an end portion of the gas discharge pipe OP.

The first collection valve IV1 may be in fluid communication with the plasma process space S1 via the first gas collection pipe IP1. The first gas collection pipe IP1 may be provided between a second recess R2 and the first collection valve IV1 so as to fluid communicate the first collection valve IV1 with the plasma process space S1. The second recess may be provided in (for example, defined or at least partially defined by) a side wall adjacent to the plasma process space S1 among the plurality of side walls 21y. For example, the first collection valve may be or include a manually operated On-Off valve, but example embodiments are not limited thereto. The On-Off valve may be, for example a valve configured to allow or block (for example, substantially block) flow which may pass therethrough.

The discharge valve OV may be in fluid communication with the first exhaust pipe 24a via the gas discharge pipe OP. The gas discharge pipe OP may be provided between the first exhaust pipe 24a and the discharge valve OV so as to be in fluid communication the discharge valve OV with an inner space of the first exhaust pipe 24a. For example, the discharge valve may be or include a manually operated On-Off valve. The On-Off valve may be or include, for example, a valve configured to allow or block (for example, substantially block) flow which may pass therethrough.

In some example embodiments, the gas supplier 50 may include, for example, a flow controller 51, a gas source 52, and a shower plate 53. The shower plate 53 may be provided in (for example, be located within a space defined or at least partially defined by) the upper wall 21x of the chamber 20. The gas supplier may be configured to supply gas to the inner space PS of the chamber. The gas may include one or more different gases in a certain (for example, desired, or alternatively, predetermined) ratio. For example, the gases may include halogenated substances such as, for example, fluorine (F), chlorine (Cl) or bromine (Br), inert substances such as argon (Ar) and helium (He), etc., but example embodiments are not limited thereto. For example, the gas may include nitrogen trifluoride (NF₃).

The gas source 52 may store one or more different gases and be in fluid communication with a plurality of through holes SH of the shower plate 53 through a plurality of gas supply lines. Gas, which may be introduced from the gas source 52, may be controlled by the flow controller 51 to maintain a desired or, alternatively, predetermined flow rate. The shower plate may be a structure configured to inject the gas, which is supplied from the gas source, into the inner space PS of the chamber 20.

In some example embodiments, the controller 60 may receive data about gas, which is supplied to the plasma process space, from the monitoring apparatus 100 and change process conditions of the plasma etching apparatus based on the data. For example, the data may be related to, for example, components of the gas and ratio of the components, but example embodiments are not limited thereto.

For example, the controller 60 may change the process conditions by controlling the pump PU connected with the gas supplier 50 and the exhaust portion 24. The controller 60 may control, for example, partial pressure(s) of gas, which may be injected into the chamber 20, by transmitting control signals to the gas supplier 50. In addition, or alternatively, the controller 60 may output control signals to the pump PU to control the inner pressure of the chamber 20.

In some example embodiments, the monitoring apparatus 100 may include a first collection line 110 and 120 that is detachably connected to the first collection valve IV1, a gas analyzer 130 configured to analyze gas, which is introduced through the first collection line 110 and 120, and a discharge line 140 and 150 that is detachably connected to the discharge valve OV and is configured to discharge gas that is analyzed by the gas analyzer 130.

For example, the monitoring apparatus may be configured to analyze gas in the plasma process space S1 to measure components of gases and ratio(s) of the components. For example, in a plasma etching process, the monitoring apparatus may be configured to measure components of etchants in the plasma process space and ratio(s) of components. The monitoring apparatus may be detachably connected to the first collection valve IV1 and the discharge valve OV, so that the monitoring apparatus may be installed at the plasma etching apparatus for process when gas analysis is desired, advantageous, or required.

The first collection line 110 and 120 may include a plurality of first collection line valves 110 that are configured to control gas introduced from the first collection valve IV1, and a plurality of first collection line pipes 120 connected to the plurality of first collection line valves 110. For example, the plurality of first collection line pipes 120 may fluidly communicate the first collection valve IV1 and the gas analyzer 130 with the plurality of first collection line valves 110.

The plurality of first collection line valves 110 may include a first inlet flow control valve 112 and a first on-off valve 114 in sequential fluid communication with the first collection valve IV1 through the plurality of first collection line pipes 120. The plurality of first collection line pipes 120 may include first to third collection line pipes 120a, 120b, 120c. The first collection line pipe 120a may connect the first collection valve IV1 and the first inlet flow control valve 112, the second collection line pipe 120b may connect the first inlet flow control valve 112 and the first on-off valve 114, and the third collection line pipe 120c may connect the first on-off valve 114 with the gas analyzer 130.

The first inlet flow control valve 112 may control a flow rate of gas, which is introduced from the first collection valve IV1. The first inlet flow control valve 112 may control the flow rate of gas to maintain or alter a pressure in the gas analyzer 130 to be, for example, equal to or less than a maximum pressure measurable by the gas analyzer 130, or substantially so. For example, the first inlet flow control valve may be a needle valve, but example embodiments are not limited thereto.

The first on-off valve 114 may allow or block gas which is introduced from the first collection valve IV1 to the gas analyzer 130. The first on-off valve 114 may be controlled, for example, automatically controlled, to turn the valve on and off. A data storage device may be connected to the first on-off valve 114 to store, for example continuously store, gas analysis data that is measured during the etching process. The first on-off valve 114 may control, for example automatically control, an operation (on/off) of the gas analyzer 130 such that the gas analyzer 130 is turned on when (for example, only when) the etching process is performed. Accordingly, a lifetime of the gas analyzer 130 may be extended.

The gas analyzer 130 may be a device configured to measure components of the gas and a ratio of components in the plasma process space S1. For example, the gas analyzer may be a residual gas analyzer (RGA) that ionizes the introduced gas by using an internal filament to measure a concentration of the ionized gas, but example embodiments are not limited thereto.

The discharge line 140 and 150 may include a plurality of discharge line pipes 140 and an outlet flow control valve 150 configured to control a flow rate of the gas discharged to the exhaust portion 24. For example, the plurality of first outlet line pipes 140 may allow fluid communication of the gas analyzer 130 and the discharge valve OV with the outlet flow control valve 150. For example, the plurality of first outlet line pipes 140 may include a first outlet line pipe 140a connecting the gas analyzer 130 and the outlet flow control valve 150 and a second outlet line pipe 140b connecting the outlet flow control valve 150 and the discharge valve OV.

The outlet flow control valve 150 may be provided between the gas analyzer 130 and the exhaust portion 24 and be configured to control a flow of the gas, which moves from the gas analyzer 130 to the exhaust portion 24, in order to maintain the gas analyzer 130 at a desired, for example constant, pressure level. For example, the outlet flow control valve may be a throttle valve, but example embodiments are not limited thereto.

For example, in case that the pressure within the gas analyzer 130 becomes relatively low, the outlet flow control valve may reduce a cross-sectional area of an inner passage through which the flow moves to increase the pressure within the gas analyzer 130. The outlet flow control valve may prevent or reduce the likelihood of the pressure within the gas analyzer from being kept too low, and accordingly prevent or reduce the likelihood of a measurement signal of the gas analyzer from becoming less than a noise signal. Further, in case that the pressure within the gas analyzer 130 becomes relatively high, the outlet flow control valve may increase the cross-sectional area of the inner passage through which the flow moves to reduce the pressure within the gas analyzer 130. Accordingly, the outlet flow control valve may prevent or reduce the likelihood or magnitude of damage to the gas analyzer from being by pressure within the gas analyzer remaining too high.

Although the figures illustrate that the plasma etching apparatus includes the plasma control portion, the present inventive concepts are not limited thereto. Accordingly, the present inventive concepts may not include the plasma control portion, so the present inventive concepts may be applied to, for example, a dry etching process utilizing gas.

As described above, the plasma etching apparatus 10 may include the chamber 20 having the inner space PS, the substrate stage 30 provided in the chamber 20 and on which the wafer is loaded, the gas supplier 50 configured to inject the gas into the chamber 20, the controller 60, and the plasma control portion. The plasma control portion may include the antenna 25 configured to generate the plasma within the chamber 20 and the source power circuitry 40 configured to apply high frequency power to the antenna. Additionally, the plasma etching apparatus may include the valve mechanism VA in fluid communication with the inner space of the chamber 20, and the monitoring apparatus 100 that is detachably connected with the valve mechanism VA and is configured to analyze the gas within the chamber 20.

The monitoring apparatus may include the first inlet flow control valve 112, the first on-off valve 114, the gas analyzer 130, and the outlet flow control valve 150 that are sequentially arranged to be in fluid communication with each other.

Accordingly, the monitoring apparatus may measure the components of etching species and the ratio of etching species, which may contact (for example, directly contact) the wafer, from the gas in the plasma process space S1. Accordingly, feedback may be performed based on the measured composition and ratio to maintain process performance at desired, for example constant, levels.

Furthermore, the first on-off valve 114 may, for example, automatically, allow or block (for example, substantially block or hinder) the flow therethrough and may control the operation (on/off) of the gas analyzer 130 depending on whether the etching process is in progress.

Accordingly, the first on-off valve may operate the gas analyzer when, for example, only when, the etching process is in progress, to accordingly extend the life of the gas analyzer.

Furthermore, the outlet flow control valve 150 may control the flow rate of gas discharged from the gas analyzer 130 to the exhaust portion 24, to thereby maintaining a pressure within the gas analyzer 130 at a desired, for example, constant, pressure level.

Accordingly, the outlet flow control valve may prevent or reduce the likelihood and/or magnitude of damage to the gas analyzer. The outlet flow control valve may maintain an intensity of the analysis gas at, for example, a sufficiently large value compared to an intensity of the noise signal.

Hereinafter, etching methods using the plasma etching apparatus in accordance with some example embodiments will be described.

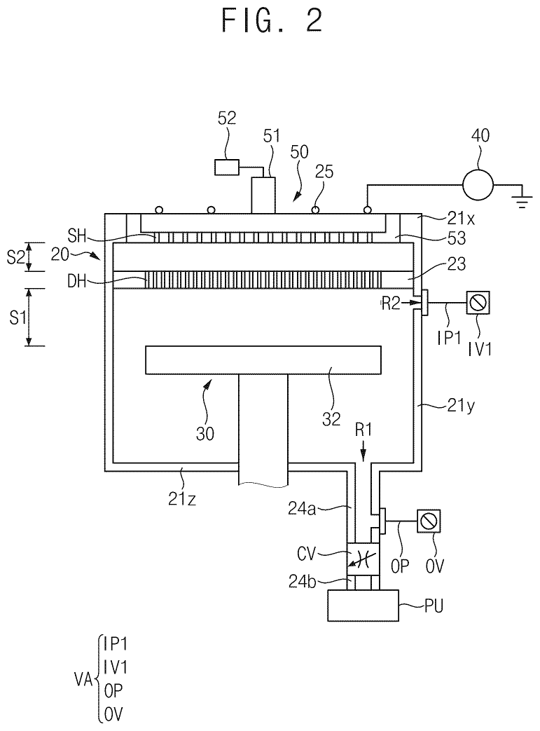

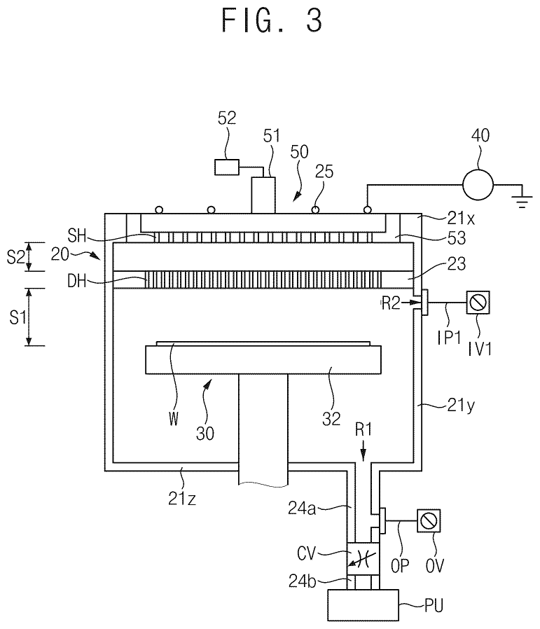

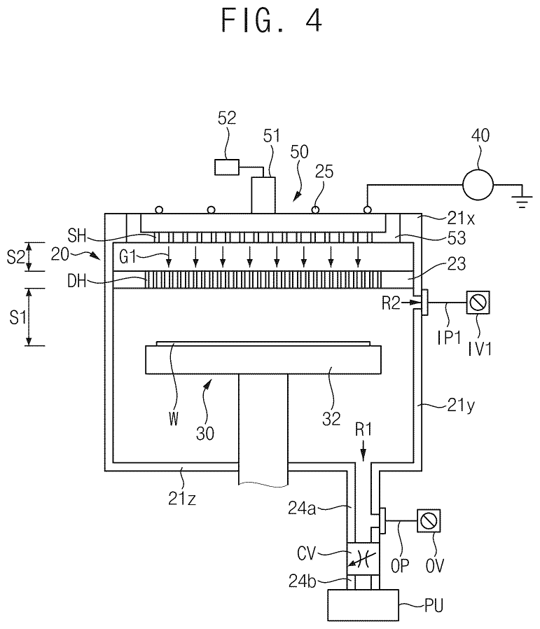

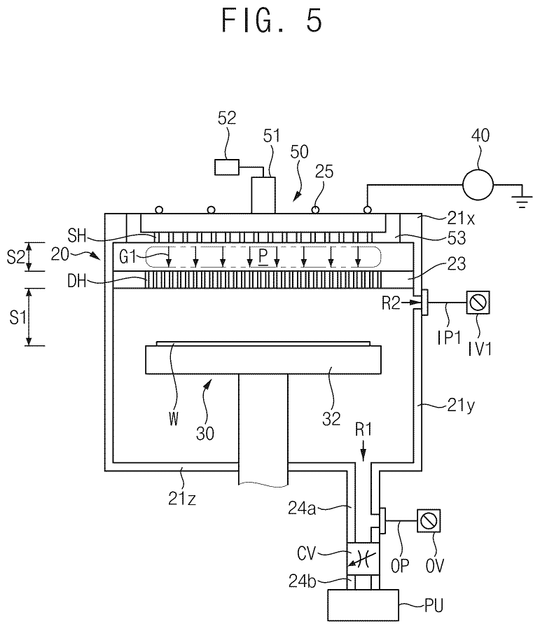

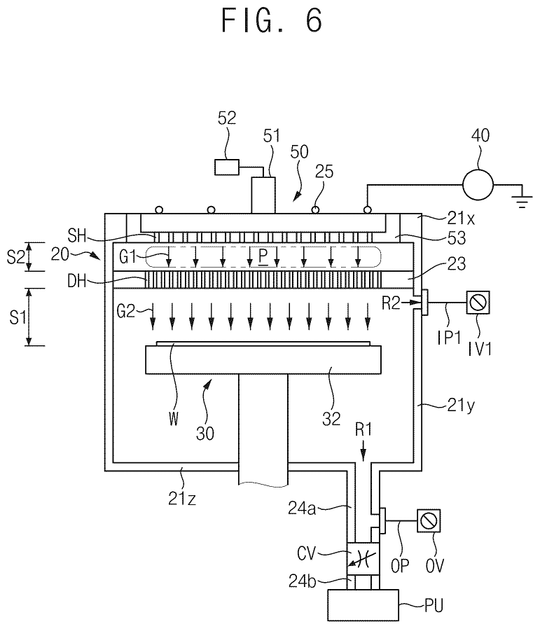

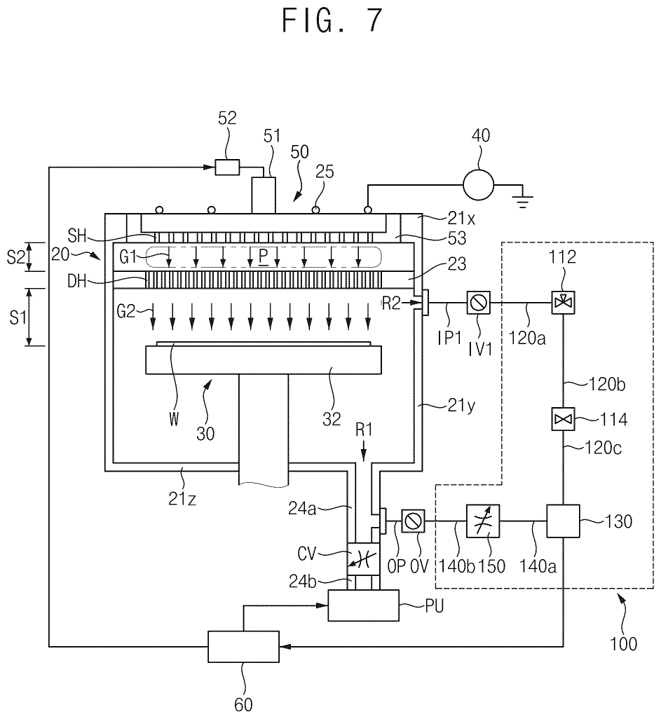

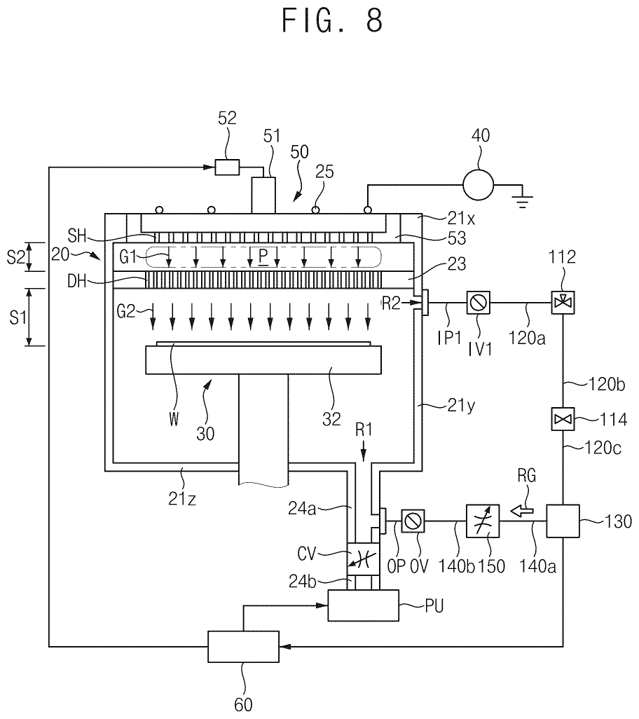

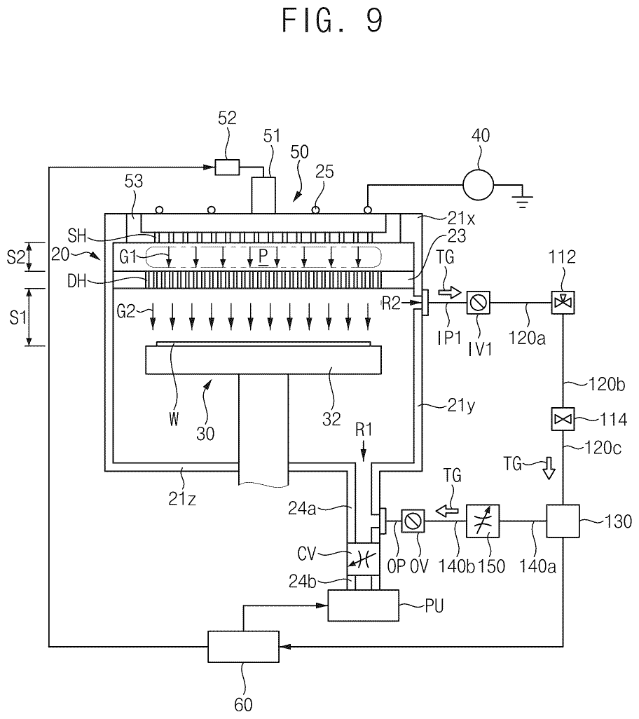

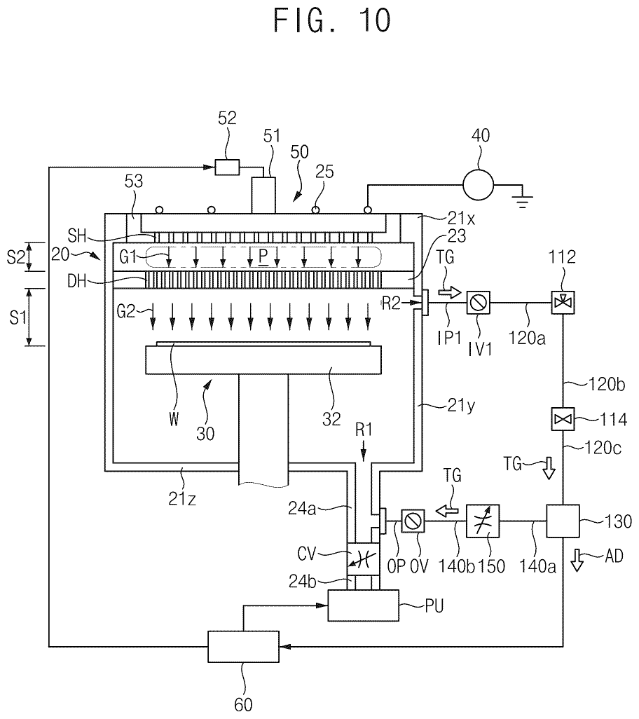

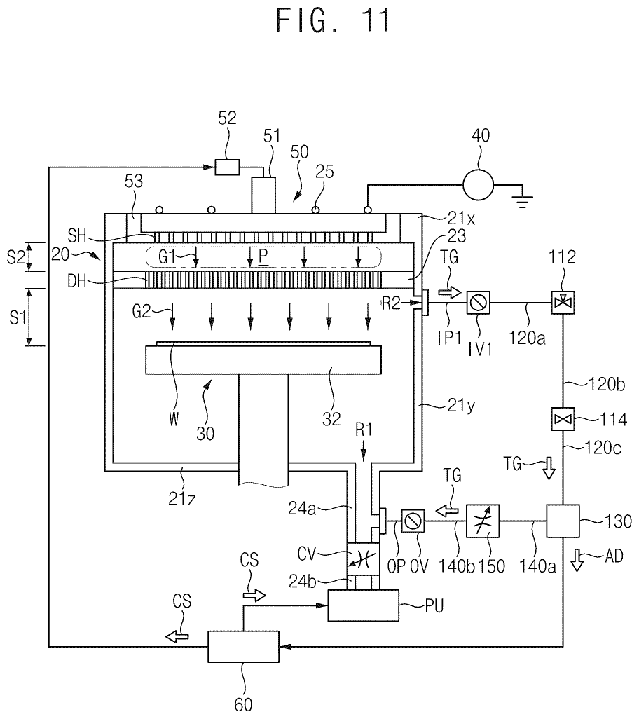

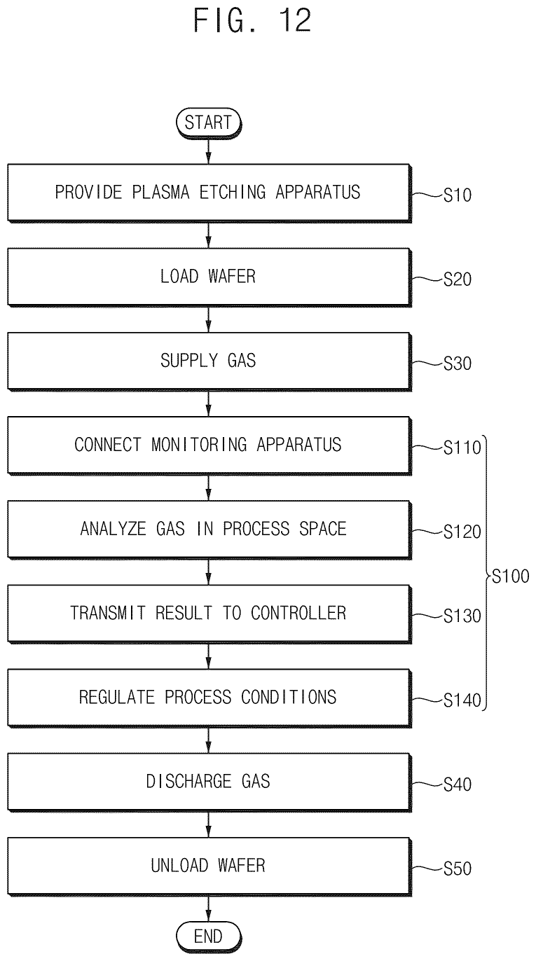

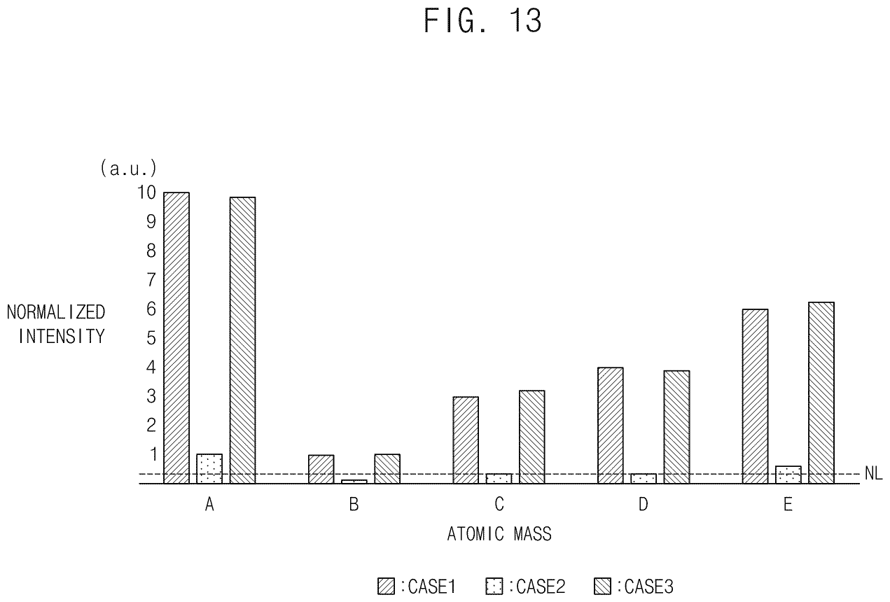

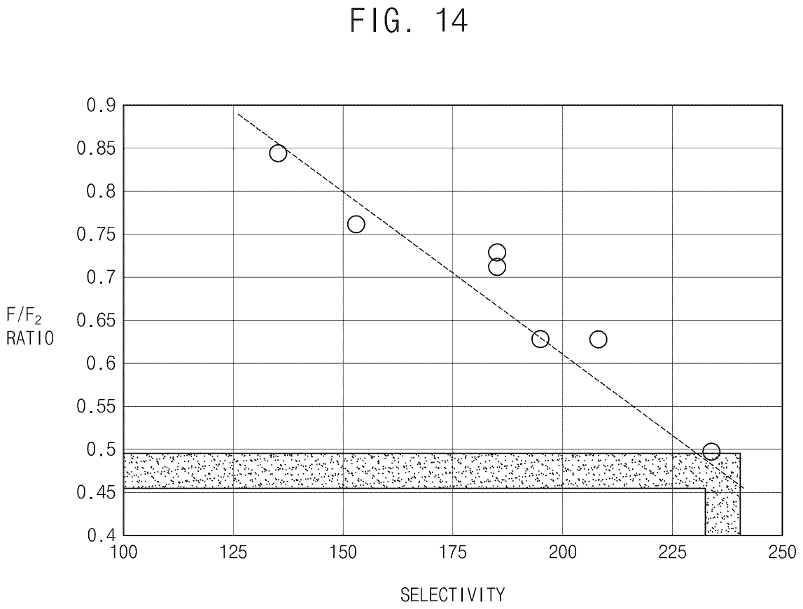

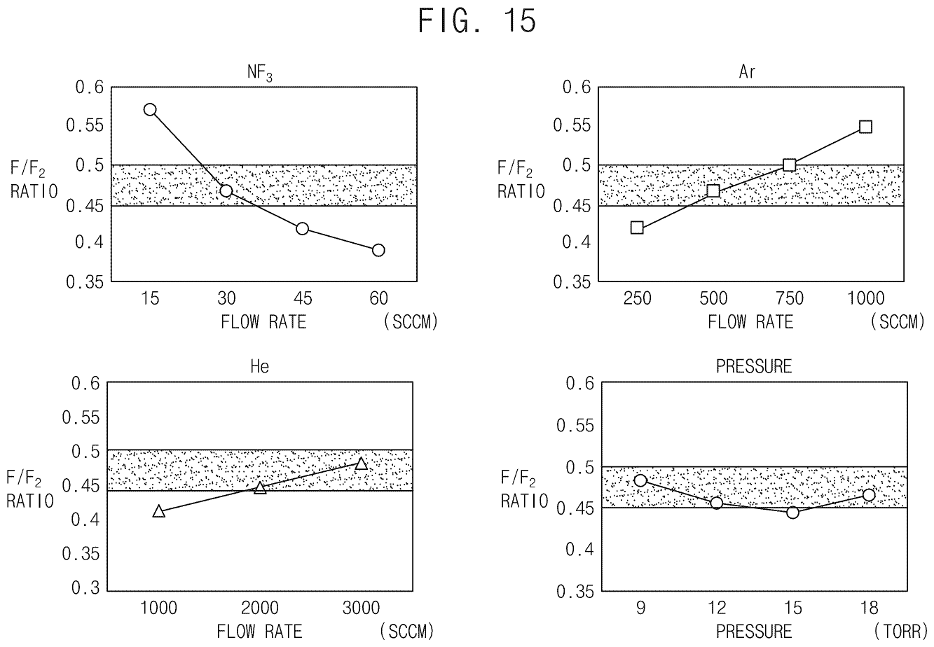

FIG. 2 is a view illustrating the plasma etching apparatus in FIG. 1, wherein the monitoring apparatus is omitted. FIG. 3 is a view illustrating the plasma etching apparatus in FIG. 2, wherein a wafer is loaded. FIG. 4 is a view illustrating that gas is injected into the plasma etching apparatus in FIG. 3. FIG. 5 is a view illustrating plasma is formed in the plasma etching apparatus in FIG. 4. FIG. 6 is a view illustrating that a gas is supplied toward a wafer. FIGS. 7 and 8 are views illustrating that a monitoring apparatus is installed to the plasma etching apparatus in FIG. 6. FIG. 9 is a view illustrating that the gas in the plasma process space is analyzed by a gas analyzer. FIGS. 10 and 11 are views illustrating that, based on information about the gas, feedback is provided to the plasma etching apparatus in FIG. 9. FIG. 12 is a flow chart illustrating a plasma etching method in accordance with some example embodiments. FIG. 13 is a graph illustrating an effectiveness of an outlet flow control valve. FIG. 14 is a graph illustrating a correlation between ratio of etching species and a selectivity. FIG. 15 is a graph illustrating variation of a selectivity according to changes in process conditions.

Referring to FIG. 2, a plasma etching apparatus 10 may be provided, wherein the plasma etching apparatus includes a first collection valve IV1 and a discharge valve OV configured to connect a monitoring apparatus to be described later.

Since the plasma etching apparatus may be identical or substantially identical to the plasma etching apparatus 10 in accordance with the some example embodiments described in FIG. 1, repetitive descriptions of the same components will be omitted.

Referring to FIG. 3, a wafer W may be loaded onto the substrate stage 30 of the plasma etching apparatus 10. For example, the chamber 20 of the plasma etching apparatus 10 may include a gate (not illustrated) configured to load the wafer.

Referring to FIG. 4, a first gas G1 may be injected into an inner space PS of the plasma etching apparatus 10 by a gas supplier 50. For example, the first gas may include a halogenated substance such as, for example, fluorine (F), chlorine (Cl) or bromine (Br), inert substances such as argon (Ar) and helium (He), etc., but example embodiments are not limited thereto. For example, the gas may include nitrogen trifluoride (NF₃).

Referring to FIG. 5, the first gas G1 may be converted into plasma P within the distribution space S2 of the chamber 20 by using the plasma control portion of the plasma etching apparatus 10. For example, the plasma may be formed by applying energy to the first gas, and the plasma may include ions, neutral particles, radicals, electrons, etc.

Referring to FIG. 6, the first gas, which is transformed into plasma, may be converted into second gas G2 through the baffle plate 23, and the second gas G2 may be moved to the wafer W. Thereafter, the second gas G may contact the wafer W in the plasma process space S1, and the etching process may be performed. For example, the second gas may be in a state in which ions are removed from the first gas as the first gas passes through the baffle plate. Furthermore, the baffle plate may distribute the second gas such that the second gas is evenly or substantially evenly distributed over the wafer W, but example embodiments are not limited thereto.

Referring to FIGS. 7 and 8, a monitoring apparatus 100 may be connected to the chamber 20.

Specifically, while blocking or impeding flow to the monitoring apparatus 100 by using the first collection valve IV1 and the discharge valve OV, the first collection valve IV1 of the valve mechanism VA may be connected to the first collection line 110 and 120 of the monitoring apparatus 100, and the outlet valve OV of the valve mechanism VA may be connected to the discharge line 140 and 150 of the monitoring apparatus 100.

Thereafter, the discharge valve OV of the chamber 20 may be utilized to allow flow to the monitoring apparatus 100, thereby removing a residual gas RG inside the monitoring apparatus 100. Then, the first collection valve IV1 of the chamber 20 may allow flow to the monitoring apparatus 100, so that the monitoring apparatus 100 may fluid communicate with the chamber 20.

Accordingly, the monitoring apparatus 100 may be installed during the process, and during the installation of the monitoring apparatus 100, gases from the outside or the residual gases inside the monitoring apparatus 100 may be prevented from or hindered in entering the chamber 20.

Referring to FIG. 9, a test gas TG may be extracted by the monitoring apparatus 100 to analyze the gas in the plasma process space S1. The test gas may be a portion of the gas in the plasma process space S1. For example, the portion of the gas TG in the plasma process space may reach the gas analyzer 130 by passing through the first collection valve, the first inlet flow control valve, and the first on-off valve. The gas analyzer 130 may analyze the test gas to, for example, determine components of the gas and ratio of the components in the plasma process space S1. Subsequently, the analyzed test gas may be discharged to the exhaust portion 24 by passing through the outlet flow control valve and the discharge valve.

Accordingly, the gases in the plasma process space may be analyzed during the plasm etching process by using the monitoring apparatus 100.

Referring to FIGS. 10 and 11, the measured analysis data AD may be transmitted to the controller 60, and the controller 60 may perform feedback by transmitting control signals CS to the plasma etching apparatus in order to change process conditions based on the measured analysis data AD. For example, the controller may transmit control signals to the gas supplier 50 to change an amount of the injected gas based on the measured analysis data AD. Further, the controller may transmit the control signals to the exhaust portion 24 to change a pressure within the chamber 20 based on the measured analysis data AD.

Accordingly, feedback control may be performed to change process conditions based on the data of the gases in the process space. For example, etching species may be controlled, for example, automatically control, by the feedback control as in-situ feedback control. The in-situ feedback control may be a control method that ratio of the etchant species may be measured in real time, and then process parameters may be adjusted based on the measured data to keep the ratio of the etchant species at constant level. Accordingly, a process performance may be kept constant through the in-situ feedback, or substantially so.

Referring to FIG. 13, a measurement intensity of the gas according to the components of the gas may be illustrated, wherein the gas is measured by the gas analyzer 130. Case 1 may illustrate a case where a pressure in the chamber is relatively strong. Case 2 may illustrate a case where the pressure in the chamber is relatively weak and the pressure in the gas analyzer 130 is not regulated by using the outlet flow control valve 150. Case 3 may illustrate a case where the pressure in the chamber is relatively weak and the pressure in the gas analyzer 130 is regulated by using the outlet flow control valve 150. Also, a baseline NL may be an intensity of unintended noise measured by the gas analyzer 130.

In case that the pressure in the gas analyzer 130 is not regulated by using the outlet flow control valve 150, the measured intensity of the components of the gas may be less than the baseline NL. Accordingly, the gas may not be properly measured due to noise signals. In contrast, in case that the pressure within the gas analyzer 130 is regulated by using the outlet flow control valve 150, the measured intensity of the components of the gas may remain relatively greater than the NL even when the pressure within the chamber 20 is reduced.

Accordingly, the outlet flow control valve 150 may help the gas analyzer 130 analyze the gas in the plasma process space S1 regardless of changes in the inner pressure of the chamber 20.

Referring to FIGS. 14 and 15, a relationship between a gas composition ratio of the plasma process space and a selectivity may be illustrated. Furthermore, a performance of feedback variables may be compared. The feedback variables may include, for example, variables for feedback control of the gas composition ratio of the plasma process space.

As illustrated in FIG. 14, the gas in the plasma process space may include, for example, fluorine atoms (F) and fluorine molecules (F₂). A correlation between the ratio of the fluorine atoms (F) and fluorine molecules (F₂) and a selectivity of silicon germanium (SiGe) may exist. For example, the selectivity may be a percentage of a silicon germanium (SiGe) film that is removed compared to a silicon (Si) film during performing the etching process.

Further, the colored region in FIG. 14 may be a ratio of the fluorine atoms (F) and fluorine molecules (F₂) corresponding to the desired selectivity.

Therefore, a ratio of the gas in the plasma process space S1 may be measured by the monitoring apparatus 100, and process conditions may be changed by determining whether the measured value is within the range corresponding to the desired selectivity.

Referring again to FIG. 15, a responsiveness of the variables for controlling the ratio of fluorine atoms (F) and fluorine molecules (F₂) may be illustrated. For example, the variables may include a flow rate of nitrogen trifluoride (NF₃) gas, a flow rate of argon (Ar) gas, a flow rate of helium (He) gas, and a pressure within the chamber 20.

It may be measured how the ratio of fluorine atoms (F) to fluorine molecules (F₂) changes by varying the variables.

In the case of the flow rate of nitrogen trifluoride (NF₃) gas, it can be seen that the ratio changes by 0.18 while the flow rate of nitrogen trifluoride (NF₃) gas changes by ‘45 sccm’. In the case of the flow rate of argon (Ar) gas, it can be seen that the ratio changed by 0.13 while the flow rate of argon (Ar) gas changes by ‘750 sccm’. In a case of the flow rate of helium (He) gas, it can be seen that the ratio changes by 0.03 while the flow rate of helium (He) gas changes by ‘2000 sccm’. In a case of the pressure in the chamber 20, it can be seen that the ratio changes by ‘0.04’ while the pressure in the chamber changes by ‘9 Torr’.

Therefore, among the variables, the change in the ratio of fluorine atom (F) and fluorine molecule (F₂) due to the change in nitrogen trifluoride (NF₃) is the greatest, so it is most effective to control the flow rate of nitrogen trifluoride (NF₃) for feedback control. However, this is only an example, so various variables may be controlled to change the ratio of fluorine atoms (F) and fluorine molecules (F₂) in the actual process.

As described above, in the etching method in accordance with some example embodiments, the plasma etching apparatus 10 may be connected with the monitoring apparatus 100. The gases in the plasma process space S1 may be analyzed by using the monitoring apparatus 100. Based on the analyzed data, the plasma etching apparatus 10 may be feedback controlled.

Accordingly, the monitoring apparatus may measure the components and ratio of the etching species, which is in contact with the wafer, from the gas in the plasma process space. Accordingly, feedback may be performed based on the measured composition and ratio to keep a process performance at desired, for example, constant, level.

Hereinafter, a plasma etching apparatus 11 in accordance with some example embodiments will be described.

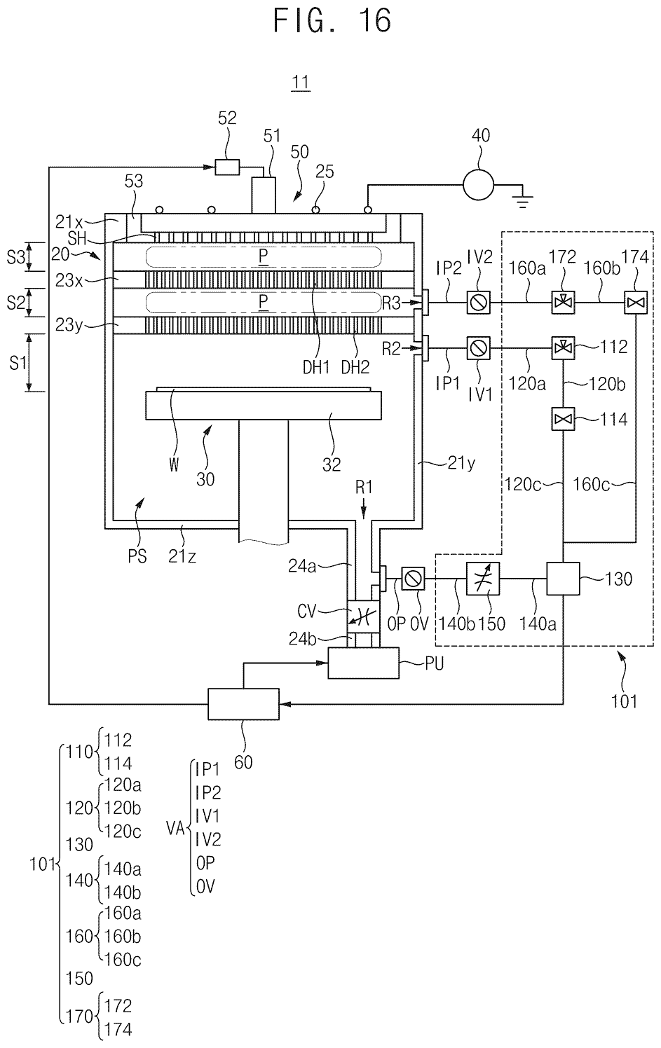

FIG. 16 is a cross-sectional view illustrating a plasma etching apparatus in accordance with some example embodiments.

Referring to FIG. 16, a plasma etching apparatus 10 may include a chamber 20 having an inner space PS, a substrate stage 30 provided within the chamber 20 and on which a wafer is loaded, a gas supplier 50 configured to inject a gas into the chamber 20, a controller 60, and a plasma control portion. The plasma control portion may include an antenna 25 configured to form plasma within the chamber 20 and a source power circuitry 40 configured to apply a high frequency power source to the antenna. Additionally, the plasma etching apparatus may include a valve mechanism VA that is in fluid communication with an inner space of the chamber 20 and a monitoring apparatus 101 that is detachably connected to the valve mechanism VA and is configured to analyze the gas in the chamber 20.

Since the plasma etching apparatus is substantially the same as the plasma etching apparatus 10 in accordance with some example embodiments described in FIG. 1 except for the chamber 20, the valve mechanism VA and the monitoring apparatus 100, a repetitive description of the same components will be omitted.

In some example embodiments, the chamber 20 may include chamber outer walls 21 defining an interior space PS, a plurality of baffle plates 23x and 23y configured to distribute the injected gas, an exhaust portion 24 provided on a portion of the chamber outer walls 21 to be in fluid communication with the inner space PS, and an antenna 25 provided on the chamber 20. For example, the inner space of the chamber may be sealed and the inner pressure may be regulated by the exhaust portion, but example embodiments are not limited thereto.

The chamber outer walls 21 may include an upper wall 21x with a gas supplier to be described later, a lower wall 21z with an exhaust portion 24, and a plurality of side walls 21y provided between the upper wall 21x and the lower wall 21z and defining the inner space PS.

The substrate stage 30 may include a substrate support 32 configured to load the wafer W (for example, to have the wafer W loaded thereon) and be provided within the inner space PS of the chamber 20. For example, the substrate support may include a seated surface configured to load the wafer W (for example, to have the wafer W loaded thereon) and opposite the upper wall.

The plurality of baffle plates 23x and 23y may be disposed between the substrate stage 30 and the upper wall 21x of the chamber 20, and each of the plurality of baffle plates 23x and 23y may have a plurality of gas passages DH1 and DH2.

The inner space PS may include a first distribution space S2, a second distribution space S3, and a plasma process space S1 sequentially arranged between the gas supplier 50 and the wafer W. The first distribution space and the second distribution space may be spaces where the injected gas is converted into plasma. Although the figures illustrate that the gas in the first distribution space and the second distribution space is converted into plasma, the present inventive concepts may not be limited to this. Accordingly, a space in which plasma is formed in the first distribution space and the second distribution space may be changed.

The plurality of baffle plates 23x, 23y may include a first baffle plate 23x disposed between the first distribution space S2 and the second distribution space S3 and a second baffle plate 23y disposed between the first distribution space S2 and the plasma process space S1. The first distribution plate may have a plurality of first gas distribution holes DH1 inside, and the second distribution plate may have a plurality of second gas distribution holes DH2 inside. The plurality of baffle plates may, for example, filter ions from gas passing through the plurality of first gas distribution holes and the plurality of second gas distribution holes. Further, the plurality of baffle plates may be structures configured to distribute gas so that the gas is, for example, evenly or substantially evenly distributed over the plasma process space S1. For example, the plasma gas in the first distribution space may include ions. In contrast, for example, the plasma gas in the second distribution space may not include ions, but example embodiments are not limited thereto.

Although figures illustrate that the plasma P is provided in the first and second distribution spaces S2 and S3 between the plurality of baffle plates 23 and the chamber upper wall 21x, the present inventive concepts may not be limited to this. Accordingly, the plasma may be varied according to the plasma control portion.

In some example embodiments, the valve mechanism VA may include a first gas collection pipe IP1 which is in fluid communication with the plasma process space S1 in the chamber 20, a first collection valve IV1 provided at an end of the first gas collection pipe IP1, a gas discharge pipe OP which is in fluid communication with the exhaust pipes 24a and 24b, and a discharge valve OV provided at an end of the gas discharge pipe OP. The valve mechanism VA may further include a second gas collection pipe IP2 which is in fluid communication with the first distribution space S2 in the chamber 20 and a second collection valve IV2 provided at an end of the second gas collection pipe IP2.

The first collection valve IV1 may be in fluid communication with the plasma process space S1 via the first gas collection pipe IP1. The first gas collector pipe IP1 may be provided between the first collection valve IV1 and the second recess R2, which is provided on a side wall adjacent to the plasma process space S1 among the plurality of side walls, to fluid communicate the plasma process space S1 with the first collection valve IV1. For example, the first collection valve may be or include a manually operated On-Off valve. The On-Off valve may be or include a valve configured to allow or block (for example, substantially block) flow.

The discharge valve OV may be in fluid communication with the first exhaust pipe 24a via a gas discharge pipe OP. The gas discharge pipe OP may be provided between the first exhaust pipe 24a and the discharge valve OV to fluid communicate an inner space of the first exhaust pipe 24a with the discharge valve OV. For example, the discharge valve may be or include a manually operated On-Off valve, but example embodiments are not limited thereto. The On-Off valve may be or include a valve configured to allow or block (for example, substantially block) flow.

The second collection valve IV2 may be in fluid communication with the first distribution space S2 via a second gas collection pipe IP2. The second gas collection pipe IP2 may be provided between the second collection valve IV2 and a third recess R3, which is provided on an outer wall adjacent to the first distribution space S2 among the plurality of sidewalls 21y, to fluidly communicate the first distribution space S2 with the second collection valve IV2. For example, the second collection valve may be or include a manually operated On-Off valve. The On-Off valve may be a valve configured to allow or block (for example, substantially block flow).

In some example embodiments, the monitoring apparatus 101 may include a first collection line 110 and 120 that is detachably connected to the first collection valve IV1, a second collection line 160 and 170 that is detachably connected to the second collection valve IV2, a gas analyzer 130 that is configured to analyze a gas introduced through the first collection line 110 and 120 and the second collection line 160 and 170, and a discharge line 140 and 150 that is detachably connected to the discharge valve OV and is configured to discharge the gas analyzed by the gas analyzer 130. The monitoring apparatus may be detachably connected to the first collection valve IV1, the second collection valve IV2 and the discharge valve OV, so that the monitoring apparatus may be installed to the plasma etching apparatus when gas analysis is required or desired.

The second collection lines 160, 170 may include a plurality of second collection line valves 170 configured to control the gas introduced from the second collection valve IV2 and a plurality of second collection line pipes 160 connecting the plurality of second collection line valves 170. For example, the plurality of second collection line pipes 160 may allow fluid communication between the second collection valve IV2, the gas analyzer 130, and the plurality of second collection line valves 170.

The plurality of second collection line valves 170 may include, for example, a second inlet flow control valve 172 and a second on-off valve 174 in sequential fluid communication with the second collection valve IV2 through the plurality of second collection line pipes 160. The plurality of second collection line pipes 160 may include fourth to sixth collection line pipes 160a, 160b, 160c. For example, the fourth collection line pipe 160a may connect the second collection valve IV2 to the second inlet flow control valve 172, and the fifth collection line pipe 160b may connect the second inlet flow control valve 172 to the second on-off valve 174, and the sixth collection line pipe 160c may connect the second on-off valve 174 to the gas analyzer 130, but example embodiments are not limited thereto.

The second inlet flow control valve 172 may control a flow rate of gas introduced from the second collection valve IV2. The second inlet flow control valve 172 may control the flow rate of the gas in order to, for example, maintain pressure within the gas analyzer 130 to be equal to or less than a maximum pressure measurable in the gas analyzer 130, or substantially so. For example, the second inlet flow control valve may be or include a needle valve, but example embodiments are not limited thereto.

The second on-off valve 174 may be configured to allow or block (for example, substantially block) the flow of the gas from the second collection valve IV2 to the gas analyzer 130. The second on-off valve 174 may be controlled, for example, automatically controlled, to turn the valve On-Off (for example, control an On/Off operation thereof). A data storage device may be connected to the second on-off valve 174 to store, for example continuously store, gas analysis data that is measured during the process, or substantially so. For example, second on-off valve 174 may control, for example automatically control, an operation (On/Off) of the gas analyzer 130 only when the plasma etching process is in progress. Accordingly, the lifespan of the gas analyzer 130 may be extended.

Accordingly, the components of the gas and the ratio of the components in the plasma process space S1 and the first distribution space S2 may be measured by using the plasma etching apparatus 11. Accordingly, a difference in the concentration of the etching species in the plasma process space S1 and the first distribution space S2 may be measured. Furthermore, it is possible to determine what changes occur in the gas injected into the chamber 20 during the etching process. Furthermore, based on the difference in the concentration of the etching species in the plasma process space S1 and the first distribution space S2, a preventive (for example, preventative) maintenance interval of the plasma etching apparatus may be calculated.

Hereinafter, a plasma etching plasma etching apparatus 12 in accordance with some example embodiments will be described.

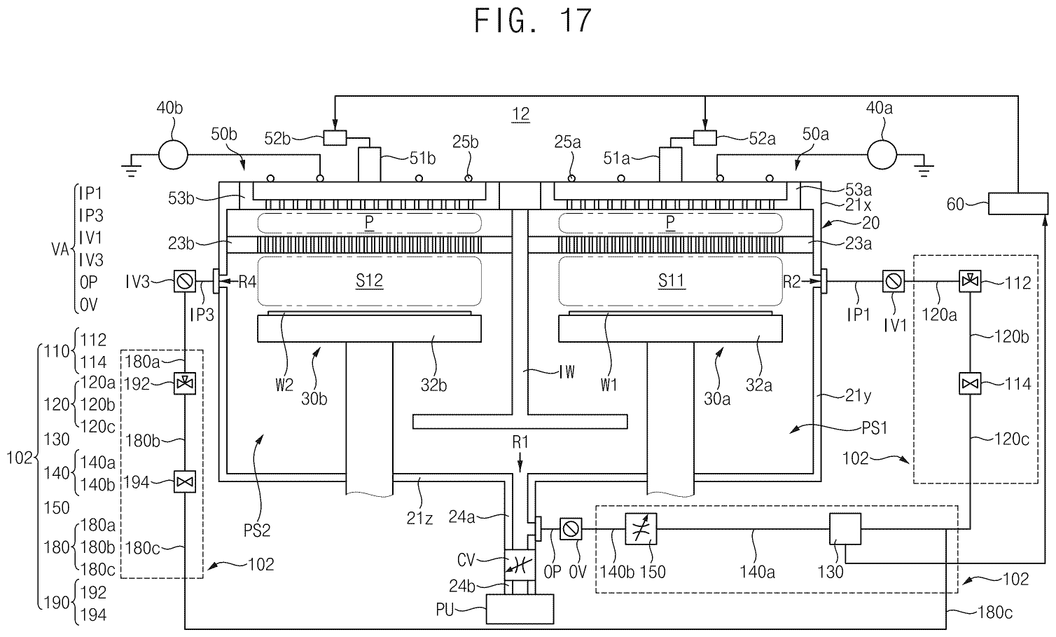

FIG. 17 is a cross-sectional view illustrating a plasma etching apparatus in accordance with some example embodiments.

Referring to FIG. 17, the plasma etch apparatus 12 may include a chamber 20 having (for example, defining or at least partially defining) a plurality of inner spaces PS1, PS2, a plurality of substrate stages 30a, 30b provided in each of the plurality of inner spaces PS1, PS2 and on which wafers are loaded, a plurality of gas suppler 50a and 50b configured to inject a gas into the plurality of inner spaces PS1 and PS2, a controller 60 and a plasma control portion. The plasma control portion may include a plurality of antennas 25a and 25b configured to form plasma within the chamber 20 and a source power circuitry 40a and 40b configured to apply high frequency power to the plurality of antennas. Additionally, or alternatively, the plasma etching apparatus may include a valve mechanism VA that is in fluid communication with each of the plurality of inner spaces and a monitoring apparatus 102 configured to analyze gas (for example, gases) within the plurality of inner spaces.

The plasma etching apparatus 12 may be the same or substantially the same as the plasma etching apparatus 10 in accordance with some example embodiments described in FIG. 1 except for the chamber 20, the valve mechanism VA, the monitoring apparatus 102 and the number of components, so that a repetitive description of the same components is omitted.

In some example embodiments, the chamber 20 may include chamber outer walls 21 defining a plurality of inner spaces PS1 and PS2, a plurality of baffle plates 23a, 23b configured to distribute injected gas, an exhaust portion 24 provided on a portion of the chamber outer walls 21 to be respectively in fluid communication with the plurality of inner spaces and a plurality of antennas 25a, 25b respectively provided on the chamber 20. For example, the inner spaces of the chamber may be sealed and the inner pressure may be regulated by the exhaust portion, but example embodiments are not limited thereto.

The plurality of substrate stages 30a and 30b may be respectively provided in the plurality of inner spaces PS1, PS2 of the chamber 20, and each of the plurality of substrate stages 30a and 30b may have substrate supports 32a, 32b configured to load wafers W.

The inner space of the chamber 230 may include a first inner space PS1 and a second inner space PS2 separated by an inner wall IW. The first inner space PS1 and the second inner space PS2 may respectively include first and second plasma process spaces S11 and S12 respectively disposed between the plurality of baffle plates 23a and 23b and the loaded wafers W1 and W2. The plasma process spaces may be spaces in which the injected gas is in contact with the wafers and in which the etching process is performed.

In some example embodiments, the valve mechanism VA may include a first gas collection pipe IP1 which is in fluid communication with the first plasma process space S11 in the chamber 20, a first collection valve IV1 provided at an end portion of the first gas collection pipe IP1, a gas discharge pipe OP which is in fluid communication with the exhaust pipes 24a, 24b, and a discharge valve OV provided at an end portion of the gas discharge pipe OP. Further, for example, the valve mechanism VA may include a third gas collection pipe IP3 which is in fluid communication with the second plasma process space S12 in the chamber 20 and a third collection valve IV3 provided at an end portion of the third gas collection pipe IP3, but example embodiments are not limited thereto.

The third collection valve IV3 may be in fluid communication with the second plasma process space S12 via the third gas collection pipe IP3. The third gas collection pipe IP3 may be provided between the fourth recess R4 and the first collection valve IV1 on a side wall adjacent to the second plasma process space S12 among the plurality of side walls to fluid communicate the second plasma process space S12 and the third collection valve IV3 with each other. For example, the third collection valve may be or include a manually operated On-Off valve, but example embodiments are not limited thereto. The On-Off valve may be a valve configured to, for example, allow or block (for example, at least substantially block) flow.

In some example embodiments, the monitoring apparatus 101 may include a first collection line 110 and 120 that is detachably connected to the first collection valve IV1, a third collection line 180 and 190 that is detachably connected to the third collection valve IV3, a gas analyzer 130 that is configured to analyze the gas introduced through the third collection line 180 and 190, and an discharge line 140 and 150 that is detachably connected to the discharge valve OV and is configured to discharge the gas analyzed by the gas analyzer 130. The monitoring apparatus may be, for example, detachably connected to the first collection valve IV1, the third collection valve IV3 and the discharge valve OV, such that the monitoring apparatus may be connected to the plasma etching apparatus when gas analysis is desired and/or required, but example embodiments are not limited thereto.

The third collection line 180 and 190 may include a plurality of third collection line valves 190 configured to control a gas introduced from the third collection valve IV3 and a plurality of third collection line pipes 180 connecting the plurality of third collection line valves 190. For example, the plurality of third collection line pipes 180 may fluidly communicate the third collection valve IV3, the gas analyzer 130, and the plurality of third collection line valves 190 with each other.

The plurality of third collection line valves 190 may include a third inlet flow control valve 192 and a third on-off valve 194 which is in sequentially fluid communication with the third collection valve IV3 through the plurality of third collection line pipes 180. The plurality of third collection line pipes 180 may, for example, include seventh to ninth collection line pipes 180a, 180b, 180c. The seventh collection line pipe 180a may connect the third collection valve IV3 to the third inlet flow control valve 192, and the eighth collection line pipe 180b may connect the third inlet flow control valve 192 to the third on-off valve 194, and the ninth collection line pipe 190c may connect the third on-off valve 194 to the gas analyzer 130, but example embodiments are not limited thereto.

The third inlet flow control valve 192 may regulate the flow rate of gas from the third collection valve IV3. The third inlet flow control valve 192 may regulate the flow rate of gas in order to maintain (for example, regulate) pressure within the gas analyzer 130 to be about equal to or less than a maximum pressure measurable in the gas analyzer 130. For example, the third inlet flow control valve may be a needle valve, but example embodiments are not limited thereto.

The third on-off valve 194 may configured to allow or block (for example, substantially block) the flow of the gas from the third collection valve IV3 to the gas analyzer 130. The third on-off valve 194 may be automatically controlled to turn the valve On-Off. A data storage device may be connected to the third on-off valve 194 to continuously store gas analysis data that is measured during the process. The third on-off valve 194 may automatically control an operation (On/Off) of the gas analyzer 130 only when the plasma etching process is in progress. Accordingly, the lifespan of the gas analyzer 130 may be extended.

Accordingly, the components of the gas and the ratio of the gas in the first and second plasma process space S11 and S12 may be measured by using the plasma etching apparatus 12. Accordingly, the components of the gas and the ratio of the components in the plurality of plasma process spaces may be respectively measured.

The foregoing is illustrative of at least some example embodiments and is not to be construed as limiting thereof. Although a few example embodiments have been described, those ordinarily skilled in the art will readily appreciate that many modifications are possible in example embodiments without materially departing from the novel teachings and advantages of the present inventive concepts. Accordingly, all such modifications are intended to be included within the spirit and scope of example embodiments as defined in the claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other at other orientations) and the spatially relative descriptors used herein interpreted accordingly.

What is claimed is:

1. A plasma etching apparatus, comprising:
a chamber having an upper wall, a lower wall, and side walls, the side walls at least partially defining a plasma process space between the upper wall and the lower wall;
a substrate stage in the chamber and configured to support a wafer;
a gas supplier configured to supply gas onto the wafer;
a gas exhaust portion having an exhaust pipe, the exhaust pipe configured to exhaust gas from the chamber, the gas exhaust portion configured to control pressure inside the chamber;
a valve mechanism having
a first collection valve at an end portion of a first gas collection pipe, the first gas collection pipe in fluid communication with the plasma process space, and
a discharge valve at an end portion of a gas discharge pipe, the discharge pipe in fluid communication with the exhaust pipe; and
a monitoring apparatus having
a first collection line detachably connected to the first collection valve,
a gas analyzer configured to analyze gas introduced through the first collection line, and
a discharge line configured to discharge the analyzed gas.

2. The plasma etching apparatus of claim 1, further comprising:
a controller configured to receive data from the monitoring apparatus, the data indicating a ratio of the analyzed gas, and the controller configured to change a process condition of the plasma etching apparatus based on the data.

3. The plasma etching apparatus of claim 1, wherein the first collection line includes a plurality of first collection line valves and a plurality of first collection line pipes in fluid communication with the plurality of first collection line valves and with the gas analyzer.

4. The plasma etching apparatus of claim 3, wherein the plurality of first collection line valves includes a first inlet flow control valve in fluid communication with the first collection valve and a first on-off valve in fluid communication with the first inlet flow control valve.

5. The plasma etching apparatus of claim 1, wherein the discharge line includes an outlet flow control valve and a plurality of discharge line pipes, the plurality of discharge line pipes in communication with the discharge valve, the gas analyzer, and the outlet flow control valve.

6. The plasma etching apparatus of claim 1, wherein the gas analyzer is configured to analyze gas to measure a ratio of etching species in the plasma process space.

7. The plasma etching apparatus of claim 1, further comprising:
first and second baffle plates that are between the upper wall and the substrate stage and respectively define a plurality of gas distribution holes.

8. The plasma etching apparatus of claim 7, wherein the chamber includes a first distribution space between the upper wall and the first baffle plate and a second distribution space between the first baffle plate and the second baffle plate, and
wherein the valve mechanism includes a second collection valve at an end portion of a second gas collection pipe that is in fluid communication with the second distribution space.

9. The plasma etching apparatus of claim 8, wherein the monitoring apparatus includes a second collection line detachably connected to the second collection valve.

10. The plasma etching apparatus of claim 9, wherein the second collection line has a plurality of second collection line valves and a plurality of second collection line pipes, the plurality of second collection line pipes in fluid communication with the second collection valve, the gas analyzer, and the plurality of second collection line valves.

11. A plasma etching apparatus, comprising:
a chamber having an upper wall at least partially defining a plurality of through holes, a lower wall at least partially defining an exhaust hole, and side walls at least partially defining a plasma process space between the upper wall and the lower wall;
a substrate stage in the chamber and having a seated surface configured to support a wafer;
a gas supplier configured to supply gas to the wafer through a plurality of through holes at least partially defined by the chamber;
an exhaust portion having an exhaust pipe and a pump, the exhaust pipe connected to the pump, the exhaust portion configured to control pressure in the chamber;
a plasma generator configured to generate plasma from gas supplied through the plurality of through holes;
a valve mechanism having
a first collection valve at an end portion of a first gas collection pipe that is connected to the side walls of the chamber, the first gas collection pipe configured to collect gas in the plasma process space, and
a discharge valve at an end portion of a gas discharge pipe, the gas discharge pipe connected to the exhaust pipe, the exhaust pipe configured to exhaust collected gas; and
a monitoring apparatus having
a first collection line detachably connected to the first collection valve,
a gas analyzer configured to analyze gas introduced through the first collection line, and
a discharge line detachably connected to the discharge valve and configured to discharge the analyzed gas.

12. The plasma etching apparatus of claim 11, further comprising:
a controller configured to receive data from the monitoring apparatus, the data indicating a ratio of the analyzed gas, and the controller configured to change a process condition of the plasma etching apparatus based on the data.

13. The plasma etching apparatus of claim 11, wherein the first collection line includes a plurality of first collection line valves and a plurality of first collection line pipes, the plurality of first collection line pipes in fluid communication with the first collection valve, the gas analyzer, and the plurality of first collection line valves.

14. The plasma etching apparatus of claim 13, wherein the plurality of first collection line valves includes a first inlet flow control valve in fluid communication with the first collection valve, and a first on-off valve in fluid communication with the first inlet flow control valve.

15. The plasma etching apparatus of claim 11, wherein the discharge line has an outlet flow control valve and a plurality of discharge line pipes, the plurality of discharge line pipes in communication with the discharge valve, the gas analyzer, and the outlet flow control valve.

16. The plasma etching apparatus of claim 11, further comprising:
first and second baffle plates between the upper wall and the substrate stage and respectively defining a plurality of gas distribution holes.

17. The plasma etching apparatus of claim 16, wherein the chamber includes a first distribution space between the upper wall and the first baffle plate and a second distribution space between the first baffle plate and the second baffle plate, and
wherein the valve mechanism includes a second collection valve at an end portion of a second gas collection pipe, the second gas collection pipe in fluid communication with the second distribution space.

18. The plasma etching apparatus of claim 17, wherein the monitoring apparatus includes a second collection line detachably connected to the second collection valve.

19. The plasma etching apparatus of claim 18, wherein the second collection line has a plurality of second collection line valves and a plurality of second collection line pipes, the plurality of second collection line pipes in fluid communication with the second collection valve, the gas analyzer, and the plurality of second collection line valves.

20. A plasma etching apparatus, comprising:
a chamber having an upper wall at least partially defining a plurality of through holes, a lower wall at least partially defining an exhaust hole, and side walls at least partially defining a plasma process space between the upper wall and the lower wall;
a substrate stage in the chamber and configured to have a wafer loaded thereon;
a gas supplier configured to supply gas onto the wafer through the plurality of through holes;
a baffle plate between the upper wall of the chamber and the substrate stage and at least partially defining a plurality of gas distribution holes;
a gas exhaust portion having an exhaust pipe in fluid communication with the exhaust hole, a chamber outlet valve configured to control pressure in the chamber, and a pump configured to exhaust gas from the chamber;
a valve mechanism having
a first collection valve at an end portion of a first gas collection pipe, the first gas collection pipe in fluid communication with the plasma process space, and
a discharge valve at an end portion of a gas discharge pipe, the gas discharge pipe in fluid communication with the exhaust pipe;
a monitoring apparatus having a first collection line detachably connected to the first collection valve, a gas analyzer configured to analyze gas introduced through the first collection line, and a discharge line detachably connected to the discharge valve and configured to discharge the analyzed gas; and
a controller configured to receive data from the monitoring apparatus, the data indicating a ratio of the analyzed gas, and the controller configured to change a process condition of the plasma etching apparatus.
